(19) United States
(12) Patent Application Publication
(10) Pub. No.: US 2025/0247958 A1
(43) Pub. Date: Jul. 31, 2025

(54) STACKING BOARDS ON RIGID-FLEXES TO DECOUPLE DYNAMIC BENDS

(71) Applicant: Snap Inc., Santa Monica, CA (US)

(72) Inventors: Bryan Selby, Royse City, TX (US); Shu-Fong Tsau, Palatine, IL (US); Edmilson Besseler, San Jose, CA (US); Jason Heger, Louisville, CO (US)

(21) Appl. No.: 19/020,840

(22) Filed: Jan. 14, 2025

Related U.S. Application Data
(60) Provisional application No. 63/627,645, filed on Jan. 31, 2024.

(51) Int. Cl. H05K 1/14; H01L 23/538; H01L 25/18; H05K 1/02; H05K 3/36

(52) U.S. Cl. CPC H05K 1/144; H01L 23/5385; H01L 25/18; H05K 1/0277; H05K 3/361; H01L 23/5387; H05K 2201/10378

(57) ABSTRACT

A stacked printed circuit board (PCB) assembly is provided comprising a first rigid PCB having high complexity components, a dynamic bending flexible PCB, and a PCB interposer electrically interconnected between the rigid and flexible PCBs. The high complexity components may have a pin count exceeding 100 and pitch under 0.4 mm. The dynamic bending flexible PCB is optimized for flexing by using fabrication processes unsuitable for the complexity components. The rigid and flexible PCBs are manufactured separately then integrated using the PCB interposer. This enables the rigid PCB to utilize processes for optimizing density and complexity without constraining the flexible PCB bending requirements. The discrete approach improves fabrication and bend cycle yields compared to conventional rigid-flex solutions. Reliable dynamic flexing is achieved while integrating complex components requiring rigid PCB fabrication.

### CLAIM OF PRIORITY

This patent application claims the benefit of priority to Selby et al, U.S. Provisional Patent Application Ser. No. 63/627,645, entitled “STACKING BOARDS ON RIGID-FLEXES TO DECOUPLE DYNAMIC BENDS FROM COMPLEX STACKUPS,” filed on Jan. 31, 2024, which is hereby incorporated by reference herein in its entirety.

### BACKGROUND

Flexible and rigid-flex printed circuit boards (PCBs) are sometimes incorporated into user devices that are subject to bending or flexing in use. Flexible PCBs can be used to route signals and power across hinges or other dynamic bending areas in devices like head-mounted displays and mobile phones. For example, in an augmented reality (AR) eyewear device, a flexible circuit may be required to pass through a folding hinge located near each temple of the AR eyewear device. A high degree of flexibility and “cycle-life” durability can be important for such installations.

However, integrating high complexity components like application processors, modems, and memory poses challenges when also requiring dynamic flexing on the same PCB. These components typically have high pin counts (>100) and fine pitch interconnects (<0.4 mm) which require fabrication processes not suitable for dynamic flexing areas. For example, they may require thicker copper, specialized dielectric materials, complex via structures, and plating techniques that reduce flex reliability and durability.

When high complexity components are integrated on rigid-flex PCBs requiring dynamic bending, yields during fabrication and bend cycle testing can be less than half (i.e., <50%). The fabrication processes required for the complex components can preclude optimization of the dynamic bending areas on the same PCB. This can lead to lower yields, reduced flex life, and other issues.

### BRIEF DESCRIPTION OF THE DRAWINGS

In the drawings, which are not necessarily drawn to scale, like numerals may describe similar components in different views. Some nonlimiting examples are illustrated in the figures of the accompanying drawings in which:

FIG. 1 is a perspective view of a wearable device, in accordance with some examples.

FIG. 2A and FIG. 2B illustrate a conventional PCB assembly, in accordance with some examples.

FIG. 3 illustrates aspects of a stacked PCB assembly, in accordance with some examples.

FIG. 4 illustrates a PCB interposer, in accordance with some examples.

FIG. 5 illustrates a final assembly of a stacked PCB assembly, in accordance with some examples.

FIG. 6 illustrates a cross sectional view of a stacked PCB assembly, in accordance with some examples.

FIG. 7 illustrates a flowchart of a method, in accordance with some examples.

### DETAILED DESCRIPTION

The present disclosure describes techniques for integrating high complexity electronic components requiring rigid printed circuit board (PCB) fabrication processes while also providing optimized dynamic bending flex areas. This is addressed in some examples through the use of stacked PCB assemblies and interposers.

In some examples, a stacked PCB assembly is provided comprising a first rigid PCB having one or more high complexity components coupled thereon, a dynamic bending flexible PCB, and a PCB interposer electrically connected between the first rigid PCB and dynamic bending flexible PCB. In some examples, the one or more high complexity components have a pin count exceeding 100 and a pitch of less than 0.4 mm.

The dynamic bending flexible PCB is optimized for dynamic bending by utilizing fabrication processes not compatible with the high complexity components. The PCB interposer interconnects the rigid and flexible PCBs while maintaining isolation of their respective manufacturing processes. By isolating complex components onto the first rigid PCB, the dynamic bending flexible PCB can be independently optimized for improved bending performance and durability. The stacked configuration enables integrating high complexity integrated circuits (ICs) needing rigid PCB fabrication while also providing reliable dynamic flex areas in a single assembly.

In some examples, a stacked printed circuit board (PCB) assembly is provided comprising a first rigid PCB having a first side and a second side opposite the first side, the first rigid PCB comprising one or more high complexity components coupled on the first side; a dynamic bending flexible PCB having a first side and a second side opposite the first side; and a PCB interposer electrically connected between the first rigid PCB and dynamic bending flexible PCB to form a stacked PCB assembly.

Some examples isolate complex rigid PCBs as standalone rigid boards that can tolerate complex high density interconnect (HDI) via structures and appropriate plating techniques and then interface these with a dynamic bending flex (which may be more vulnerable to plating techniques that reduce flex reliability and durability, as discussed further above) through a stacked PCB. By doing so, more optimal practice fabrication processes can be used independently on both the rigid board and on the dynamic bending flex since they are separate during fabrication.

The one or more high complexity components on the rigid PCB (and on the stacked PCB assembly accordingly) may have a pin count exceeding 100 and a pitch of less than 0.4 mm. The dynamic bending flexible PCB can be optimized for dynamic bending by utilizing fabrication processes not compatible with the one or more high complexity components. The PCB interposer electrically interconnects the first rigid PCB and the dynamic bending flexible PCB while maintaining isolation of their respective fabrication processes.

By isolating complex components onto the first rigid PCB, the dynamic bending flexible PCB can be independently optimized utilizing appropriate materials and processes to improve dynamic bending performance and durability. The stacked configuration enables integration of high complexity components requiring rigid PCB fabrication while also supporting reliable dynamic bending flex areas in a single PCB assembly.

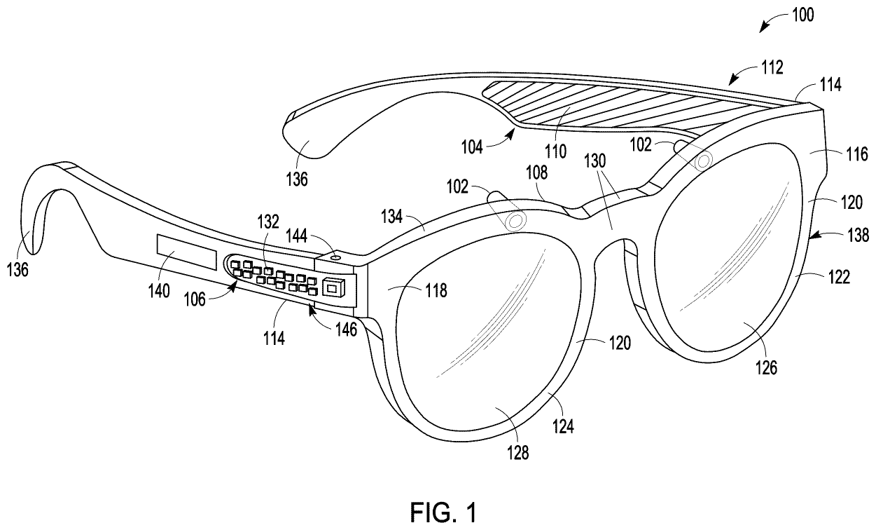

FIG. 1 shows a perspective view of a head-wearable user device, in this example shown as an AR eyewear device (e.g., the AR glasses 100), in accordance with some examples. The form factor of the AR glasses 100 is compact and space available for internal componentry is tight. The AR glasses 100, in this instance, can be worn to view augmented or virtual content displayed over real-world content visible in a content interaction system.

The example AR glasses 100 of FIG. 1 include a small frame 112 made from any suitable material such as plastic or metal, including any suitable shape memory alloy, as is known for ophthalmic eyewear. In one or more examples, the frame 112 includes a front piece 138, including a first or left (as worn by a user) optical element holder 122 (e.g., a display or lens holder) and a second or right (as worn by a user) optical element holder 124, connected by a nose piece or bridge 130. The front piece 138 additionally includes a left end portion 116 and a right end portion 118. A first or left optical element 126 and a second or right optical element 128 can be provided within respective left optical element holder 122 and right optical element holder 124. Each of the right optical element 128 and the left optical element 126 can be a lens, a display, a display assembly, or a combination of the foregoing. Any of the display assemblies disclosed herein can be provided in the AR glasses 100.

The frame 112 additionally includes a left arm or temple piece 104 and a right arm or temple piece 106 coupled to the respective left end portion 116 and the right end portion 118 of the front piece 138 by any suitable means such as at a folding hinge 144 (one folding hinge 144 on each side), so as to be coupled to the front piece 138, or rigidly or otherwise secured to the front piece 138 so as to be integral with the front piece 138. In one or more implementations, each of the temple pieces 104 and 106 includes a first portion 114 that is coupled to the respective left end portion 116 and right end portion 118 of the front piece 138 and any suitable second portion 136 for coupling to the ear of the user. In one or more examples, the front piece 138 can be formed from a single piece of material, so as to have a unitary or integral construction. In some examples, such as illustrated in FIG. 1, the entire frame 112 can be formed from a single piece of material so as to have a unitary or integral construction.

The AR glasses 100 can include a computing device, such as a computer 132, which can be of any suitable type so as to be carried by the frame 112 and, in one or more examples of a suitable size and shape, so as to be at least partially disposed in one of the temple pieces 104 and the temple pieces 106. In one or more examples, as illustrated in FIG. 1, the computer 132 is sized and shaped similar to the size and shape of one of the temple pieces 106 (e.g., or the temple piece 104), and is thus disposed almost entirely, if not entirely, within the structure and confines of such temple piece 106. In one or more examples, the computer 132 is disposed in both of the temple piece 104 and the temple piece 106, and flexible circuits that connect the two parts of the computer 132 pass through one of (or both) the folding hinges 144. The computer 132 can include one or more printed circuit boards (PCBs) and one or more hardware processors with memory, wireless communication circuitry, and a power source. In some examples, the computer 132 comprises low-power circuitry, high-speed circuitry, and a display processor. Various other examples may include these elements in different configurations or integrated together in different ways.

The computer 132 additionally includes a battery 110 or other suitable portable power supply. In some examples, the battery 110 is disposed in one of the temple pieces 104 or the temple piece 106. In the AR glasses 100 shown in FIG. 1, the battery 110 is shown as being disposed in left temple piece 104 and electrically coupled using the connection 134 to the remainder of the computer 132 disposed in the right temple piece 106. The AR glasses 100 can include a connector or port (not shown) suitable for charging the battery 110 accessible from the outside of frame 112, a wireless receiver, transmitter, or transceiver (not shown) or a combination of such devices.

In one or more implementations, the AR glasses 100 include cameras 102. Although two cameras 102 are depicted, other examples contemplate the use of a single or additional (i.e., more than two) cameras. In one or more examples, the AR glasses 100 include any number of input sensors or peripheral devices in addition to the cameras 102. The front piece 138 is provided with an outward facing, forward-facing, or front or outer surface 120 that faces forward or away from the user when the AR glasses 100 are mounted on the face of the user, and an opposite inward-facing, rearward-facing, or rear or inner surface 108 that faces the face of the user when the AR glasses 100 are mounted on the face of the user. Such sensors can include inwardly-facing video sensors or digital imaging modules, such as cameras that can be mounted on or provided within the inner surface 108 of the front piece 138 or elsewhere on the frame 112 so as to be facing the user, and outwardly-facing video sensors or digital imaging modules such as the cameras 102 that can be mounted on or provided with the outer surface 120 of the front piece 138 or elsewhere on the frame 112 so as to be facing away from the user. Such sensors, peripheral devices or peripherals can additionally include biometric sensors, location sensors, or any other such sensors. In one or more implementations, the AR glasses 100 include a track pad 140 or other touch or sensory input device to receive navigational commands from the user. One or more track pads 140 may be provided at convenient locations for user interaction on one or both sides of the temple piece 104 and/or the temple piece 106.

In some examples, a PCB of the computer 132 includes a flexible section or hinge region 146. In some examples, the hinge region 146 is located at or adjacent to the folding hinge 144. More specifically, the hinge region 146 may be located in a region either side of, or crossing, a folding hinge 144. The hinge region 146 adjacent a folding hinge 144 may undergo a significant degree of bending, flexing, or movement when the arms or temple pieces 104 and 106 of the AR glasses 100 are opened and closed, for example.

As mentioned above, however, integrating high complexity components like application processors, complex components, and memory into such a region poses challenges when requiring dynamic flexing on the same PCB. These components typically have high pin counts (>100) and fine pitch interconnects (<0.4 mm) which require fabrication processes not suitable for dynamic flexing areas. For example, they may require thicker copper, specialized dielectric materials, complex via structures, and plating techniques that reduce flex reliability and durability.

When high complexity components are integrated on rigid-flex PCBs requiring dynamic bending, yields during fabrication and bend cycle testing are often less than 50%. The fabrication processes required for the complex components essentially preclude optimization of the dynamic bending areas on the same PCB. This leads to lower yields, reduced flex life, and other issues. Some examples herein seek to address these problems by enabling the integration of high complexity electronic components requiring rigid PCB fabrication processes while also providing optimized dynamic bending flex areas. The present disclosure includes techniques for achieving this through the use of stacked PCB assemblies and interposers.

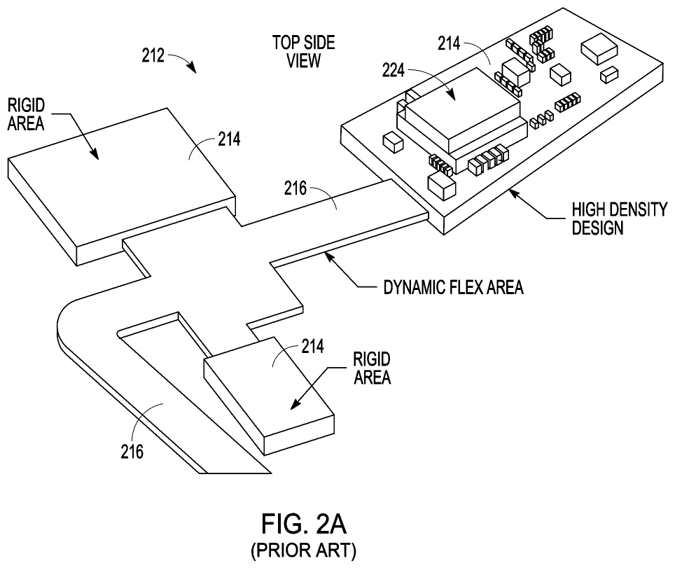

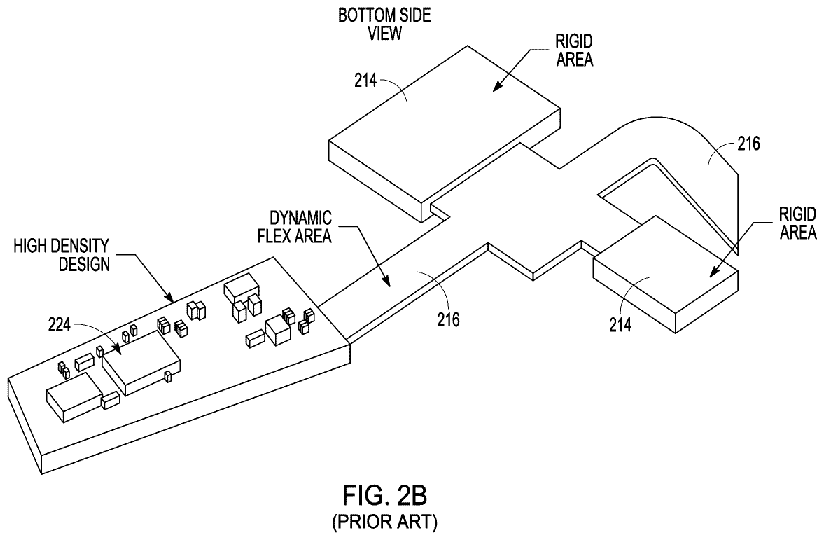

Reference is now made to FIG. 2A which shows a pictorial view of a top side of a conventional PCB assembly 212, also known as a Rigid-Flex Printed Circuit Board (RFPCB). The PCB assembly 212 comprises “rigid” areas or regions including rigid PCBs 214 and adjacent “flexible” areas or regions including flexible PCBs 216, also known as Flexible Printed Circuit Boards (FPCs). An underside or bottom side view of the PCB assembly 212 is shown in FIG. 2B. The top and/or bottom side of a rigid PCB 214 may include complex components 224 as shown. These areas of the complex components 224 may also be known as high-density areas and these areas are not easily rendered flexible, if at all.

In some instances, enabling a dynamic bending of conventional FPCs and/or RFPCBs requires specific copper, plating, materials, and/or feature sizes that do not support high complexity chipsets, for example high complexity chip sets having a high pin count (for example, >100), and/or a fine pitch (for example <0.40 mm) ball grid arrays (BGAs). In seeking to provide dynamic bending, it has been found that implementing high complexity chipsets in an RFPCB that requires dynamic bending (for example, repeated bending through the folding hinge 144 of the glasses 100 of FIG. 1) results in production yields less than 50% during fabrication and bend cycle testing failure rates in excess of 50% due to the fact that the high complexity chipsets are rendered substantially inflexible by the incorporation of special copper, plating, materials, and/or feature sizes that are not conducive to dynamic bending.

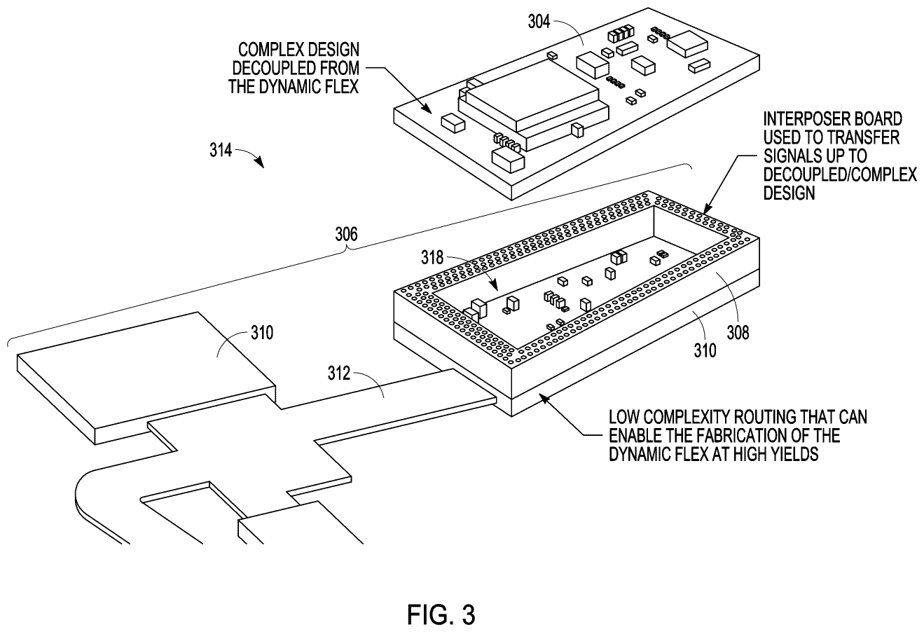

To address these challenges, reference is now made to FIG. 3 to FIG. 6. Some examples herein employ “decoupled” or separately manufactured rigid printed circuit boards (PCBs) to isolate such complex circuitry that has high pin counts and small pitch ball grid arrays (BGAs), for example. The separately manufactured rigid PCBs are coupled or connected after manufacture to a simpler and more dynamic flexible printed circuit (FPC) or rigid-flex PCB through a custom stacked PCB interposer. The separately manufactured rigid PCBs can accommodate the complex circuitry and high density interconnects (HDIs), for example, and their manufacturing processes can be separately optimized to that end. On the other hand, the “decoupled” FPC or rigid-flex PCB can be separately optimized for dynamic bending by using appropriate materials, feature sizes, and plating. Decoupling for separate manufacture the complex rigid PCBs from the dynamic flex PCB enables improved flexibility and bend cycle life. Some examples thus combine the benefits of HDIs and complex circuitry with improved dynamic flexing in a same overall, stacked PCB assembly. Some examples isolate complex rigid PCBs from a less complex dynamic bending section using a stacked PCB interposer to improve overall flexibility and functionality of a stacked PCB assembly.

Reference is now made to FIG. 3 in this regard that shows a stacked PCB assembly 314 according to some examples. The stacked PCB assembly 314 is manufactured by isolating complex chipsets and associated complex manufacturing processes to a separately manufactured complex rigid PCB 304. The separately manufactured complex rigid PCB 304 is then coupled or otherwise electrically connected to a separately manufactured RFPCB 306 (or, in some examples, to an FPC) through a stacked PCB interposer 308. In this way, the complexity of making the stacked PCB assembly 314 and installing complex components on it is decoupled from the significantly more complex methods of making a conventional and more failure-prone PCB assembly 212. The stacked PCB assembly 314 nevertheless still enables overall acceptable dynamic bending flex capabilities and functional performance for a device, such as the glasses 100.

The RFPCB 306 of FIG. 3 includes rigid PCBs 310 (or rigid areas) and flexible PCBs 312 (or flexible areas, or “flex”). The rigid PCBs 310 may, or may not, include further complex rigid PCBs 304. A rigid PCB 310 supporting the PCB interposer 308 and forming part of the RFPCB 306 includes relatively low complexity routing and components 318 enabling fabrication of the RFPCB 306 at higher yields and lower failure rates than the conventional PCB assembly 212. Similarly, as some or all of the low complexity routing and components 318 have been removed from the complex rigid PCB 304, the complex rigid PCB 304 can be designed using less dense PCB designs and fabricated at relatively high yields as compared to a rigid PCB 214 with the complex components 224 of the conventional PCB assembly 212 of FIG. 2A and FIG. 2B.

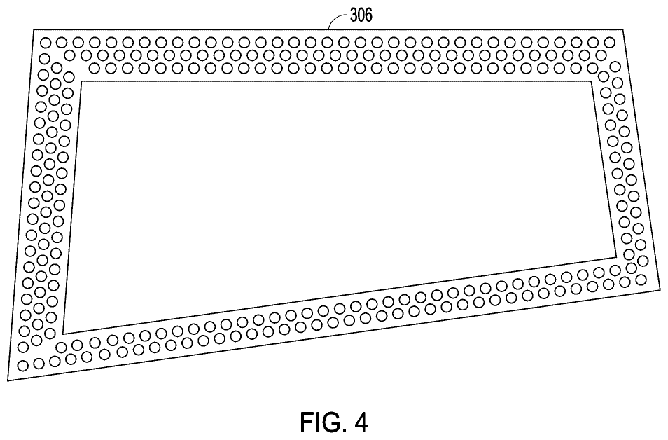

With reference to FIG. 4, the routing circuitry, traces, and/or via density of the PCB interposer 308 that connects to one side of the complex rigid PCB 304 can be matched and rendered more simply and cost effectively, accordingly.

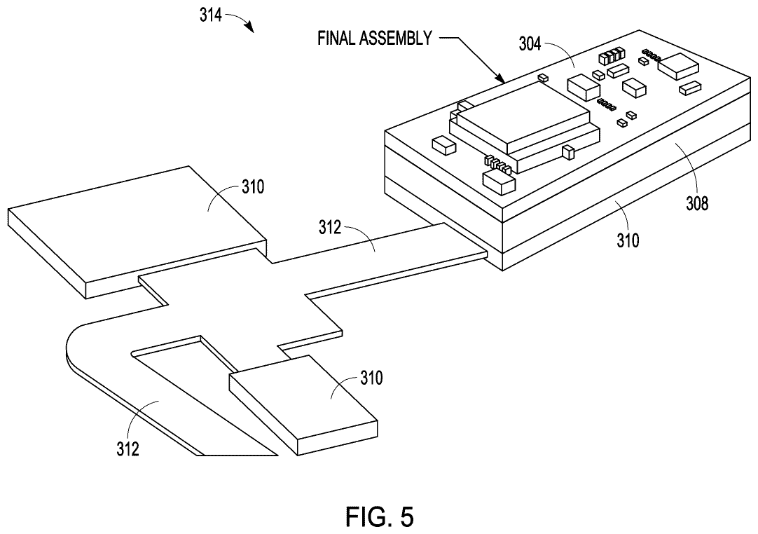

FIG. 5 shows a final assembly of the stacked PCB assembly 314 with the PCB interposer 308 coupled to one side of the rigid PCB 304 on a first face of the PCB interposer 308, and couple to a rigid PCB 310 on a second side of the PCB interposer 308. The interposer is an important component in the stacked PCB assembly, serving as the electrical bridge between the rigid PCB and the dynamic bending flexible PCB. The joining process of the interposer to the PCB assembly is designed to ensure robust electrical connections while maintaining the integrity of the separate PCBs. Initially, in some examples, the interposer is prepared by pre-bumping with a high-temperature solder alloy on the bottom side (in the view) that connects to the RFPCB, and a low-to-mid temperature solder alloy on the top side that connects to the top PCB (in the view).

The interposer is then accurately positioned and soldered to the RFPCB using standard surface-mount technology (SMT) methods. This process seeks to ensure a strong mechanical and electrical bond between the interposer and the RFPCB, capable of withstanding the dynamic bending stresses encountered during the operation of the device.

Following the attachment of the interposer to the RFPCB, an additional soldering process is employed to join the top PCB. Solder flux is dispensed on the low-to-mid temperature alloy bumps of the interposer, which are already soldered to the RFPCB. The top PCB is then placed on top of the pre-bumped interposer. The entire assembly undergoes a low-to-mid temperature soldering thermal cycle, designed to melt only the low-to-mid temperature solder. This selective reflow process ensures that the high-temperature solder joints on the RFPCB side remain intact, preventing any remelting and preserving the previously established connections. This example approach to assembling the stacked PCB allows for the independent optimization of the rigid and flexible PCBs as their respective soldering processes do not interfere with one another. The result is a dependable stacked PCB assembly that benefits from the robustness of high-temperature soldering for the RFPCB and the flexibility of low-to-mid temperature soldering for the top PCB, facilitating dynamic bending capabilities without compromising the structural integrity of the high complexity components.

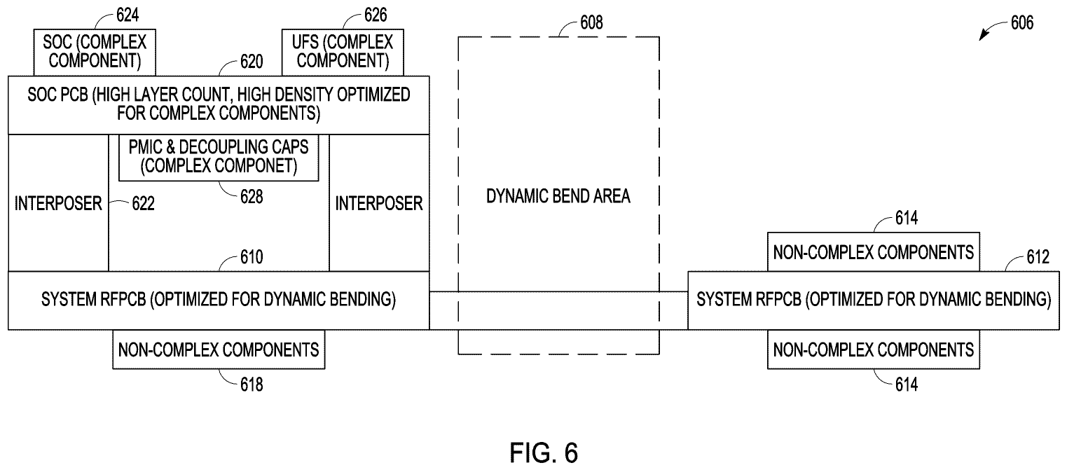

FIG. 6 shows a cross-sectional view of an example stacked PCB assembly 606. The stacked PCB assembly 606 includes a dynamic bend area 608 in a flexible area (or FCP in some examples) located between a first system RFPCB 610 and a second system RFPCB 612. The first system RFPCB 610 and second system RFPCB 612 may be separately manufactured to optimize dynamic bending. The first system RFPCB 610 and the second system RFPCB 612 may form part of a larger or composite RFPCB, such as the RFPCB 306 of FIG. 3. The first system RFPCB 610 may include or support one or more non-complex components 618, as shown. The second system RFPCB 612 may include or support one or more non-complex components 614, as shown.

The stacked PCB assembly 606 also includes a complex rigid PCB 620 supported by and electrically connected to one side of a PCB interposer 622. The complex rigid PCB 620 has a high layer count and a high density, for example high pin counts (>100) and fine pitch interconnects (<0.4 mm). To this end, the complex rigid PCB 620 is separately manufactured in some examples, for example as described above for the complex rigid PCB 304. The complex rigid PCB 620 may include one or more Systems-on-a-Chip (SOCs 624), Universal Flash Storage (UFS 626), power management integrated circuits (PMICs) and decoupling caps 628. In some examples, the SOCs 624, the UFS 626, and the PMICs and decoupling caps 628 are complex components, in other words have high pin counts (>100) and fine pitch interconnects (<0.4 mm) in some examples. The PCB interposer 622 is supported on and electrically connected on its other side to the first system RFPCB 610.

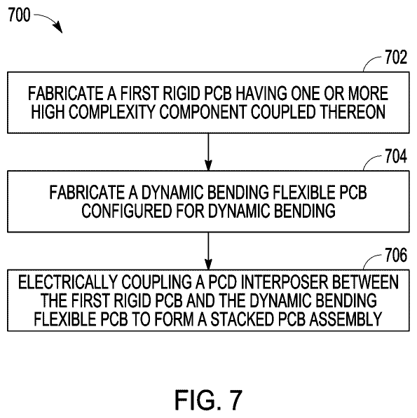

The present disclosure also includes method examples. FIG. 7 is a flowchart showing example operations in a method of manufacturing a stacked printed circuit board (PCB) assembly. Although the described flow diagram below can show operations as a sequential process, many of the operations can be performed in parallel or concurrently. In addition, the order of the operations may be re-arranged. A process is terminated when its operations are completed. A process may correspond to a method, a procedure, an algorithm, or similar. The operations of methods may be performed in whole or in part, may be performed in conjunction with some or all of the operations in other methods, and may be performed by any number of different systems, or any portion thereof in any such order, such as a processor included in any of the systems.

In operation 702, method 700 fabricates a first rigid PCB having one or more high complexity components coupled thereon. In operation 704, method 700 fabricates a dynamic bending flexible PCB configured for dynamic bending. In operation 706, method 700 electrically couples a PCB interposer between the first rigid PCB and the dynamic bending flexible PCB to form a stacked PCB assembly.

In some examples, fabricating the first rigid PCB includes fabricating the first rigid PCB using processes not compatible with dynamic bending requirements. In some examples, fabricating the dynamic bending flexible PCB includes fabricating the dynamic bending flexible PCB using processes not compatible with the one or more high complexity components. The method may further include evaluating a dynamic bending of the dynamic bending flexible PCB after formation of the stacked PCB assembly. In some examples, electrically coupling the PCB interposer includes aligning and adhering the PCB interposer between the first rigid PCB and the dynamic bending flexible PCB. The method may further include clamping alignment fixtures to apply pressure during adhering. In some examples, the adhering includes using anisotropic conductive film (ACF) or non-conductive adhesive (NCA). The method may further include, prior to coupling the PCB interposer, coupling a second rigid PCB to a second side of the first rigid PCB opposite the PCB interposer. In some examples, the stacked PCB assembly forms part of an electronic device and the dynamic bending flexible PCB extends across a hinged area of the electronic device. In some examples, the first rigid PCB and the dynamic bending flexible PCB are communicatively coupled using a conductive adhesive. Other technical features may be readily apparent to one skilled in the art from the following figures, descriptions, and claims.

In some examples, specific materials used in the rigid PCB of a stacked PCB assembly 314 or stacked PCB assembly 606 (for example the rigid PCB 310, the complex rigid PCB 304, or the complex rigid PCB 620) comprises a ceramic-filled resin. In some examples, a flexible PCB of the stacked PCB assembly 314 or the stacked PCB assembly 606 (for example flexible PCB 312, the first system RFPCB 610, or the second system RFPCB 612) comprises polyimide. In some examples, the interposer of the stacked PCB assembly 314 or the stacked PCB assembly 606 (for example the PCB interposer 308 or the PCB interposer 622) comprises glass cloth reinforced epoxy laminate.

In some examples, a rigid PCB of the stacked PCB assembly 314 or stacked PCB assembly 606 is fabricated using a build-up process. In some examples, a flexible PCB of the stacked PCB assembly 314 or stacked PCB assembly 606 is fabricated by a roll-to-roll process. In some examples, the PCB interposer 308 or PCB interposer 622 comprises microvias with a diameter less than 0.15 mm. In some examples, the electrical connections in a stacked PCB assembly 314 or stacked PCB assembly 606 use anisotropic conductive film (ACF). In some examples, one or more high complexity components (for example the complex components of the complex rigid PCB 304 of the complex rigid PCB 620) comprise a 5G modem and/or a HBM2 memory.

In some examples, a flexible PCB of the stacked PCB assembly 314 of the stacked PCB assembly 606 comprises embedded passive components. In some examples, peripheral components are mounted to a flexible PCB using a chip-on-flex process.

In some examples, the complex rigid PCB 304 or the flexible PCB 312 has trace density exceeding 200 mm/layer. In some examples, the PCB interposer 308 has thickness less than 0.8 mm.

In some examples, a flexible PCB or dynamic bend area of the stacked PCB assembly 314 or the stacked PCB assembly 606 forms part of a hinge in a foldable display, or a VR headset accommodating head motion. In some examples, the stacked PCB assembly 314 is implemented in an augmented reality head-mounted display device, such as the glasses 100.

In some examples, a flexible PCB, for example the dynamic bend area 608, or the flexible PCB 312, or the first system RFPCB 610, or the second system RFPCB 612, extends across the hinge (for example the folding hinge 144) between a front unit housing optical components and a rear unit housing electronics and a battery. The flexible PCB routes signals to peripheral microphones, cameras, and other components while avoiding interference in the bend area.

In some examples, a rigid PCB, for example the complex rigid PCB 304 or the complex rigid PCB 620, is stacked on top via the interposer, for example the PCB interposer 308 or the PCB interposer 622, and houses a main application processor, memory, and a modem providing computing power for the AR device.

In another example, the stacked PCB assembly 314 or stacked PCB assembly 606 is implemented in a foldable smartphone or tablet device. The high complexity components like the application processor, 5G modem, and memory are isolated on a rigid PCB while the flexible PCB provides dynamic bending across the fold line. The flexible PCB can route signals to and from the display, cameras, fingerprint sensors, and other components placed around the foldable device. The rigid and flexible PCBs are sandwiched together with the interposer along one edge that serves as the device's fold line during use.

In some examples, the rigid and flexible PCBs are fabricated separately using optimized materials and processes. For example, the rigid PCB may utilize more layers and complex lamination processes not suitable for flexible PCBs requiring high dynamic bendability. The interposer provides a thin, high-density interconnect to bridge between the two fabricated PCBs. Conductive adhesives, clips, or other techniques may fasten the overall stacked assembly together while maintaining electrical connectivity.

Examples of this disclosure differentiate from conventional solutions by isolating the high complexity ICs onto separate rigid PCB assemblies that are discretely fabricated and optimized. The dynamic bending flexible PCB is likewise optimized independently for bending motion rather than constrained by the dense component requirements. An interposer is used to provide high-density signal routing between the rigid and flexible assemblies.

By decoupling the fabrication processes, the respective PCBs can utilize materials and designs ideal for their requirements. No specialty dielectric flex materials, plating techniques, or complex rigid-flex processing is required. In turn, fabrication and bend cycle yields are improved along with flex durability and reliability. The discrete approach enables a modular, optimized design benefiting both the complex ICs and dynamic bending support simultaneously.

### EXAMPLES

Thus, some examples of this disclosure include the following.

Example 1. A stacked printed circuit board (PCB) assembly comprising a first rigid PCB having a first side and a second side opposite the first side, the first rigid PCB comprising one or more high complexity components coupled on the first side; a dynamic bending flexible PCB having a first side and a second side opposite the first side; and a PCB interposer electrically connected between the first rigid PCB and the dynamic bending flexible PCB to form the stacked PCB assembly.

Example 2. The assembly of example 1, wherein the one or more high complexity components has a pin count exceeding 100 and a pitch of less than 0.4 mm.

Example 3. The assembly of example 1 or example 2, wherein the dynamic bending flexible PCB is configured for dynamic bending by utilizing fabrication processes not compatible with the one or more high complexity components.

Example 4. The assembly of any one of examples 1-3, wherein the PCB interposer electrically interconnects the first rigid PCB and the dynamic bending flexible PCB while maintaining isolation of their respective fabrication processes.

Example 5. The assembly of any one of examples 1-4, further comprising a second rigid PCB coupled to the second side of the first rigid PCB.

Example 6. The assembly of any one of examples 1-5, wherein the dynamic bending flexible PCB comprises an area free of the first rigid PCB and allowing dynamic flexing across a bend radius of 5 mm or less.

Example 7. The assembly of any one of examples 1-6, wherein the PCB interposer and first rigid PCB form a rigid PCB sub-assembly electrically coupled to the dynamic bending flexible PCB.

Example 8. The assembly of example 7, wherein the rigid PCB sub-assembly has a maximum thickness of 1 mm.

Example 9. The assembly of any one of examples 1-8, wherein the first rigid PCB and dynamic bending flexible PCB are communicatively coupled using a conductive adhesive.

Example 10. The assembly of any one of examples 1-9, wherein the dynamic bending flexible PCB electrically routes signals from the one or more high complexity components to peripheral components positioned on the dynamic bending flexible PCB.

Example 11. A method of manufacturing a stacked printed circuit board (PCB) assembly, the method comprising fabricating a first rigid PCB having one or more high complexity components coupled thereon; fabricating a dynamic bending flexible PCB configured for dynamic bending; electrically coupling a PCB interposer between the first rigid PCB and the dynamic bending flexible PCB to form a stacked PCB assembly.

Example 12. The method of example 11, wherein fabricating the first rigid PCB comprises fabricating the first rigid PCB using processes not compatible with dynamic bending requirements.

Example 13. The method of example 11 or example 12, wherein fabricating the dynamic bending flexible PCB comprises fabricating the dynamic bending flexible PCB using processes not compatible with the one or more high complexity components.

Example 14. The method of any one of examples 11-13, further comprising testing dynamic bending of the dynamic bending flexible PCB after formation of the stacked PCB assembly.

Example 15. The method of any one of examples 11-14, wherein electrically coupling the PCB interposer comprises aligning and adhering the PCB interposer between the first rigid PCB and the dynamic bending flexible PCB.

Example 16. The method of example 15, further comprising clamping alignment fixtures to apply pressure during adhering.

Example 17. The method of example 15 or example 16, wherein adhering comprises using anisotropic conductive film (ACF) or non-conductive adhesive (NCA).

Example 18. The method of any one of examples 11-17, further comprising, prior to coupling the PCB interposer, coupling a second rigid PCB to a second side of the first rigid PCB opposite the PCB interposer.

Example 19. The method of any one of examples 11-18, wherein the stacked PCB assembly forms part of an electronic device and the dynamic bending flexible PCB extends across a hinged area of the electronic device.

Example 20. The method of any one of examples 11-19, wherein the first rigid PCB and the dynamic bending flexible PCB are communicatively coupled using a conductive adhesive.

Example 21. The method of any one of examples 11-20, further comprising pre-bumping the PCB interposer with a high-temperature solder alloy on a first side that connects to the dynamic bending flexible PCB, and with a low-to-mid temperature solder alloy on a second side that will connect to the first rigid PCB.

Example 22. The method of example 21, wherein electrically coupling the PCB interposer to the dynamic bending flexible PCB includes using surface-mount technology (SMT) methods to solder the pre-bumped bottom side of the PCB interposer to the dynamic bending flexible PCB.

Example 23. The method of example 22, further comprising dispensing solder flux on the low-to-mid temperature solder alloy bumps of the PCB interposer, placing the first rigid PCB on top of the bumps, and subjecting the assembly to a low-to-mid temperature soldering thermal cycle that melts only the low-to-mid temperature solder alloy, thereby joining the first rigid PCB to the PCB interposer without reflowing the high-temperature solder alloy.

The various operations of example methods described herein may be performed, at least partially, with the assistance of one or more hardware processors that are temporarily configured (e.g., by software) or permanently configured to perform the relevant operations. Whether temporarily or permanently configured, such processors may constitute processor-implemented components that operate to perform one or more operations or functions described herein. As used herein, “processor-implemented component” refers to a hardware component implemented using one or more hardware processors. Similarly, the methods described herein may be at least partially processor-implemented, with a particular processor or processors being an example of hardware. For example, at least some of the operations of a method may be performed by one or more hardware processors or processor-implemented components.

While the above is a complete description of some examples of the inventive subject matter, various alternatives, modifications, and equivalents may be used. Therefore, the above description should not be taken as limiting the scope of the inventive subject matter which is defined by the appended claims.

1. A stacked printed circuit board (PCB) assembly comprising:
a first rigid PCB having a first side and a second side opposite the first side, the first rigid PCB comprising one or more high complexity components coupled on the first side;
a dynamic bending flexible PCB having a first side and a second side opposite the first side;
and a PCB interposer electrically connected between the first rigid PCB and the dynamic bending flexible PCB to form the stacked PCB assembly.

2. The assembly of claim 1, wherein the one or more high complexity components has a pin count exceeding 100 and a pitch of less than 0.4 mm.

3. The assembly of claim 1, wherein the dynamic bending flexible PCB is configured for dynamic bending by utilizing fabrication processes not compatible with the one or more high complexity components.

4. The assembly of claim 1, wherein the PCB interposer electrically interconnects the first rigid PCB and the dynamic bending flexible PCB while maintaining isolation of their respective fabrication processes.

5. The assembly of claim 1, further comprising a second rigid PCB coupled to the second side of the first rigid PCB.

6. The assembly of claim 1, wherein the dynamic bending flexible PCB comprises an area free of the first rigid PCB and allowing dynamic flexing across a bend radius of 5 mm or less.

7. The assembly of claim 1, wherein the PCB interposer and first rigid PCB form a rigid PCB sub-assembly electrically coupled to the dynamic bending flexible PCB.

8. The assembly of claim 7, wherein the rigid PCB sub-assembly has a maximum thickness of 1 mm.

9. The assembly of claim 1, wherein the first rigid PCB and dynamic bending flexible PCB are communicatively coupled using a conductive adhesive.

10. The assembly of claim 1, wherein the dynamic bending flexible PCB electrically routes signals from the one or more high complexity components to peripheral components positioned on the dynamic bending flexible PCB.

11. A method of manufacturing a stacked printed circuit board (PCB) assembly, the method comprising:
fabricating a first rigid PCB having one or more high complexity components coupled thereon;
fabricating a dynamic bending flexible PCB configured for dynamic bending;
electrically coupling a PCB interposer between the first rigid PCB and the dynamic bending flexible PCB to form a stacked PCB assembly.

12. The method of claim 11, wherein fabricating the first rigid PCB comprises fabricating the first rigid PCB using processes not compatible with dynamic bending requirements.

13. The method of claim 11, wherein fabricating the dynamic bending flexible PCB comprises fabricating the dynamic bending flexible PCB using processes not compatible with the one or more high complexity components.

14. The method of claim 11, further comprising testing dynamic bending of the dynamic bending flexible PCB after formation of the stacked PCB assembly.

15. The method of claim 11, wherein electrically coupling the PCB interposer comprises aligning and adhering the PCB interposer between the first rigid PCB and the dynamic bending flexible PCB.

16. The method of claim 15, further comprising clamping alignment fixtures to apply pressure during adhering.

17. The method of claim 15, wherein adhering comprises using anisotropic conductive film (ACF) or non-conductive adhesive (NCA).

18. The method of claim 11, further comprising, prior to coupling the PCB interposer, coupling a second rigid PCB to a second side of the first rigid PCB opposite the PCB interposer.

19. The method of claim 11, wherein the stacked PCB assembly forms part of an electronic device and the dynamic bending flexible PCB extends across a hinged area of the electronic device.

20. The method of claim 11, wherein the first rigid PCB and the dynamic bending flexible PCB are communicatively coupled using a conductive adhesive.

21. The method of claim 11, further comprising pre-bumping the PCB interposer with a high-temperature solder alloy on a first side that connects to the dynamic bending flexible PCB, and with a low-to-mid temperature solder alloy on a second side that will connect to the first rigid PCB.

22. The method of claim 21, wherein electrically coupling the PCB interposer to the dynamic bending flexible PCB includes using surface-mount technology (SMT) methods to solder a pre-bumped side of the PCB interposer to the dynamic bending flexible PCB.

23. The method of claim 22, further comprising dispensing solder flux on the pre-bumped side of the PCB interposer, placing the first rigid PCB on top of the pre-bumped side, and subjecting the PCB interposer to a low-to-mid temperature soldering thermal cycle that melts only the low-to-mid temperature solder alloy, thereby joining the first rigid PCB to the PCB interposer without reflowing the high-temperature solder alloy.
